(19) United States
(12) Patent Application Publication
(10) Pub. No.: US 2014/0175309 A1
(43) Pub. Date: Jun. 26, 2014

(54) DEVICE, APPARATUS AND METHOD

(71) Applicant: Thomas Henry Isaac, Cambridgeshire (GB)

(72) Inventor: Thomas Henry Isaac, Cambridgeshire (GB)

(21) Appl. No.: 14/236,760

(22) PCT Filed: Aug. 2, 2012
(86) PCT No.: PCT/GB2012/051873

§ 371 Date: Mar. 11, 2014

(30) Foreign Application Priority Data
Aug. 5, 2011 (GB) 1113609.0

(51) Int. Cl. H03K 5/125; G01N 21/01

(52) U.S. Cl. CPC H03K 5/125; G01N 21/01
USPC 250/573; 327/50

(57) ABSTRACT

A device (10) for determining the number of discrete events represented by an input signal is provided. The input signal may, for example, comprise pulses representing photons arriving at a detector. The device (10) may comprise a plurality, n, of comparator circuits (14) for reading the signal. For each comparator circuit (14) from i=1 to i=n, the comparator circuit (14) has a corresponding threshold value which the amplitude of a pulse representing i discrete events will exceed, but which the amplitude of a pulse representing i-1 discrete events will not exceed. Each comparator circuit (14) is arranged to output a first value when the input signal exceeds its threshold value and a second value when the input signal is less than its threshold value. The device (10) includes a counter (16) for counting the number of outputs of the first value that have been output by the plurality of comparator circuits (14).

### FIELD

The present disclosure relates to a device for determining the number of discrete events represented by an input signal which contains one or more pulses representing a plurality of discrete events. In particular, the present disclosure relates to a device for determining the number of single photon events represented in a signal received from a single photon sensitive detector. More particularly, the present disclosure relates to such devices for use in the detection of photons produced by molecules such as biomolecules, for example nucleic acids, so that the characteristics of the molecules can be investigated.

### BACKGROUND

In a system where discrete events are detected and a corresponding electrical signal is produced, each discrete event can produce a simple pulse in the signal and each simple pulse can be of substantially the same amplitude. If the simple pulses do not overlap then processing the electrical signal to determine the number of discrete events represented by the signal may be relatively straightforward. However, when the discrete events are frequent enough the simple pulses will overlap and this will produce a complex pulse in which the complex pulse will represent a plurality of discrete events. An example where the detection of discrete events may result in such a complex pulse is the detection of multiple single photon events using a single photon sensitive detector such as a silicon photomultiplier (SiPM).

Known techniques for processing the electrical output signal of a detector such as a SiPM involve analogue to digital (AD) conversion of the signal from a detector. A typical AD conversion technique will sample the signal at regular intervals, store the data and post-process the data using a suitably programmed computer. Such a technique can involve storing and processing large amounts of data. If the sampling interval is a very short, for example in the millisecond, microsecond or even nanosecond scale, then a vast of amount of data can be accumulated in a short time. For example, if each sample uses 1 byte of data and if a sample is taken every 5 nanoseconds then around 200 megabytes of data per second would be produced. Storing and post-processing the amount of data that known AD techniques would require for analysing signals representing discrete events that occur on the millisecond, microsecond or nanosecond scale (such as signals representing multiple single photon events) becomes increasingly impractical as the timescale of the events gets shorter.

Known devices for processing the electrical output signal of a detector that rely on storing and processing large amounts of data include analogue to digital capture cards, such as the PXI-9820 digitiser card made by Adlink Technology Inc or the NI PCI-6551 made by National Instruments Corporation.

US 2010/018149 A1 (Karim) and JP 04036682 A (Toshiya) disclose techniques for counting photons that employ two modes of operation. In a first mode of operation, a single comparator is used to count discrete single-photon events. If incoming photon flux exceeds a threshold such that the probability of two or more photons arriving simultaneously is high, the systems of Karim and Toshiya switch to a second mode of operation. In the second mode of operation, the number of photons arriving is estimated using integration techniques (as in Karim) or by triggering a free-running monostable multivibrator which generates synthetic digital pulses for the duration of the pileup event (as in Toshiya).

The present disclosure seeks to provide an approach that can be used to determine the number of discrete events represented by an input signal which contains a pulse profile which represents a plurality of discrete events. The present disclosure also seeks to provide an approach which is suitable for processing signals which represent events which occur on the millisecond, microsecond or nanosecond scale such as photon detection events.

### SUMMARY

An aspect of the present disclosure provides a device for determining the number of discrete events represented by an input signal. The input signal may contain one or more pulses representing a plurality of discrete events. The device may comprise a plurality, n, of comparator circuits for reading the signal, wherein for each comparator circuit from i=1 to i=n, the i^{th} comparator circuit has a corresponding threshold value which the amplitude of a pulse representing i discrete events will exceed, but which the amplitude of a pulse representing i-1 discrete events will not exceed, and wherein each comparator circuit is arranged to output a first value (e.g. TRUE) when the input signal exceeds its threshold value and a second value (e.g. FALSE) when the input signal is less than its threshold value. The device may also comprise a counter for counting the number of outputs of the first value that have been output by the plurality of comparator circuits.

By providing the plurality of comparator circuits for reading the signal and a counter for counting the number of outputs of the first value that have been output by the plurality of comparator circuits, a device that can be used to determine the number of discrete events represented by an input signal which contains a pulse profile which represents a plurality of discrete events is provided. As the number of outputs of the first value is used to count the number of events represented by the signal, the number of events can be determined and the count passed to a computer without requiring sampling and post-processing of the signal. An approach is therefore provided which is suitable for processing signals which represent events occurring on the millisecond, microsecond or nanosecond scale.

It will be appreciated that n is a numerical value of 2 or above. The number of comparator circuits, n, will be selected so that complex pulses formed of up to n simple pulses can be processed and this will depend upon the characteristics of the discrete events being investigated. Suitably, n may be between 2 and 20 in some embodiments of this disclosure. In some embodiments n may be between 4 and 10.

The device may be arranged to process the input signal as a series of time windows. For each time window, the counter can be set to zero at the beginning of the time window, and the counter can count the number of outputs of the first value that have been output by the plurality of comparator circuits in the time window. The device can output the count at the end of the time window. In this way, an approach is provided that enables a signal to be processed over any length of time. This approach is particularly suitable for processing a signal which may have periods where the amplitude of the signal is zero between groups of pulses, particularly where these periods are relatively long periods compared with the times when pulses are present in the signal. For example, when compared with a conventional AD technique no sampling of the signal in these periods is required whereas a conventional AD technique would still require sampling of the signal throughout these periods.

The time window may be in the range from 100 nanoseconds to 1 millisecond. The time window may be in the range from 500 nanoseconds to 2 microseconds. The overall length of time that the signal is processed for may be any length of time.

The counter can count the number of outputs of the first value that have been output by the plurality of comparator circuits by monitoring the first comparator circuit for a period corresponding to a full pulse profile in which the first comparator circuit has gone through a complete cycle of outputs of the second value to the first value to the second value (e.g. FALSE to TRUE to FALSE) and counting once for the output of the first value (e.g. TRUE) of the first comparator circuit and once for each output of the first value (e.g. TRUE) of the other comparator circuits during the period. Such an approach enables signals which contain multiple complex pulses to be processed.

The device can be reconfigurable through activation or deactivation of any subset of the plurality of comparator circuits to change the response of the device to the pulsed input signal. For example, the device can be reconfigured to change the number, n, of comparator circuits and the counter can be reconfigured to work with the changed number of comparator circuits.

The counter can be implemented in a field programmable gate array.

Another aspect of the disclosure provides an apparatus comprising a device as described above and a detector for detecting discrete events. The detector can be arranged to generate the signal containing one or more pulses representing a plurality of discrete events.

The detector may comprise a single photon sensitive detector and the discrete events may be single photon events. For example, the detector can comprise a silicon photomultiplier (SiPM).

The apparatus may further comprise an analysing device for investigating a molecule. The analysing device may be arranged to interact with the molecule to output photons (for example photons generated by fluorescence or Raman scattering from single or multi-photon events). The analysing device may comprise a nanopore having a detection window within or adjacent its outlet or inlet. The analysing device may be capable of plasmon resonance to produce a localised electromagnetic field which defines the detection window.

The apparatus may suitably employ multiple detectors and multiple analysing devices. For example, an array of pairs of detectors and analysing devises may be used, with each detector being arranged to detect photons generated using its paired analysing device.

Although other applications are envisaged, devices in accordance with the present disclosure are of particular use for the detection using single photon detectors of photons produced by molecules such as biomolecules or biopolymers, for example nucleic acids, so that the characteristics of the molecules can be investigated. One particular application for the device is in an apparatus designed to sequence genetic material. Specifically, devices in accordance with the present disclosure have a particular use for investigating molecules that produce photons as they are passed through a nanopore of an analysing device such as a nanodevice. Conventional techniques are not particularly suitable for investigating photons produced by such systems as will be appreciated from the following.

A single-photon sensitive detector such as a Silicon Photomultiplier (SiPM) or Single-Photon Avalanche Diode (SPAD) generally produces a short electrical signal of approximately 20 ns duration. Pulses may arrive at a rate of once every 35 ns. In the case of the signal from a SiPM, each pulse has an amplitude linearly proportional to the number of photons arriving in the period of the pulse.

If each photon event were to be processed as, for example, one byte of data then a single detector would generate data at a rate of around 30 megabytes per second. If the number of detectors is increased this leads to a data rate which would rapidly saturate an input bus of a computer. Embodiments in accordance with the present disclosure can reduce this data rate to 1 megabyte per second from a single detector, reading at a speed ideally suited, for example, to investigating photons emitted from a biomolecule such as DNA as it passes through a nanopore.

If the multi-height signal from the SiPM detector were processed using an AD conversion technique this would be inefficient as a high-speed AD conversion would be required for each detector. Such a conversion is expensive in terms of circuit complexity, parts cost, board space and scalability. Embodiments in accordance with the present disclosure can process multi-height signals from the SiPM detector efficiently by recognising that each pulse has an amplitude linearly proportional to the number of photons arriving in the period of the pulse and by providing the plurality of comparator circuits with their threshold values set accordingly and the counter to count the number of outputs of the first value (e.g. TRUE) outputted by the plurality of comparator circuits.

Accordingly, another aspect of the present disclosure provides a method of investigating a molecule comprising: translocating a molecule through an analysing device comprising a nanopore and a detection window. The detection window may be located within the nanopore or adjacent an outlet thereof and may be defined by a means for producing a localised electromagnetic field by plasmon resonance. The method may further comprise detecting photons emitted during the interaction between the localised electromagnetic field and the molecule as the molecule passes through the detection window. The method may further comprise generating a signal containing one or more pulses representing a plurality of detected photons. The method may also comprise determining the number of detected photons represented by the signal using a device in accordance with an embodiment of the present disclosure.

It will be appreciated that the nanopore may be a solid state nanopore or a biological nanopore and that the molecules themselves or tags such as fluorescent tags on the molecules may produce photons as they pass through the nanopore. Molecules which can be investigated include biomolecules such as nucleic acids (DNA or RNA) or a protein/peptide. Linear molecules such as nucleic acids or linear proteins/peptides are particularly suitable. Single-stranded nucleic acid is especially suitable.

In one embodiment, the nucleic acid is labelled with one or more markers characteristic of the four bases from which the nucleic acid is constituted and the markers are induced to emit photons by fluorescence through interaction with the localised electromagnetic field.

### BRIEF DESCRIPTION OF THE DRAWINGS

Embodiments in accordance with the present disclosure will now be described, by way of example only, with reference to the accompanying drawings in which like reference numerals are used to depict like parts. In the drawings:

FIG. 1 illustrates an apparatus comprising a detector, an embodiment of a device in accordance with the present disclosure, a digital acquisition card and a computer;

FIG. 2 illustrates a comparator circuit used in the device of FIG. 1;

FIG. 3 illustrates a signal comprising a simple pulse and the output of the comparator circuit of FIG. 2;

FIG. 4 illustrates an embodiment of a device in accordance with the present disclosure having six comparator circuits

FIG. 5a illustrates a signal comprising a sequence of pulses, and the output of the comparator circuits of the device of FIG. 4;

FIG. 5b illustrates counting the number of TRUE outputs;

FIG. 6 is a flow diagram illustrating the steps performed by the counter of the device of FIG. 4;

FIG. 7 is a flow diagram illustrating the steps performed by a detector and the device of FIG. 4;

FIG. 8 illustrates an analysing device, a detector, the device of FIG. 4, a digital acquisition card, and a computer; and

FIG. 9 is a flow diagram illustrating the steps performed in accordance with an embodiment of the present disclosure.

### DETAILED DESCRIPTION OF EMBODIMENTS

Embodiments of devices in accordance with the present disclosure are for determining the number of discrete events represented by an input signal.

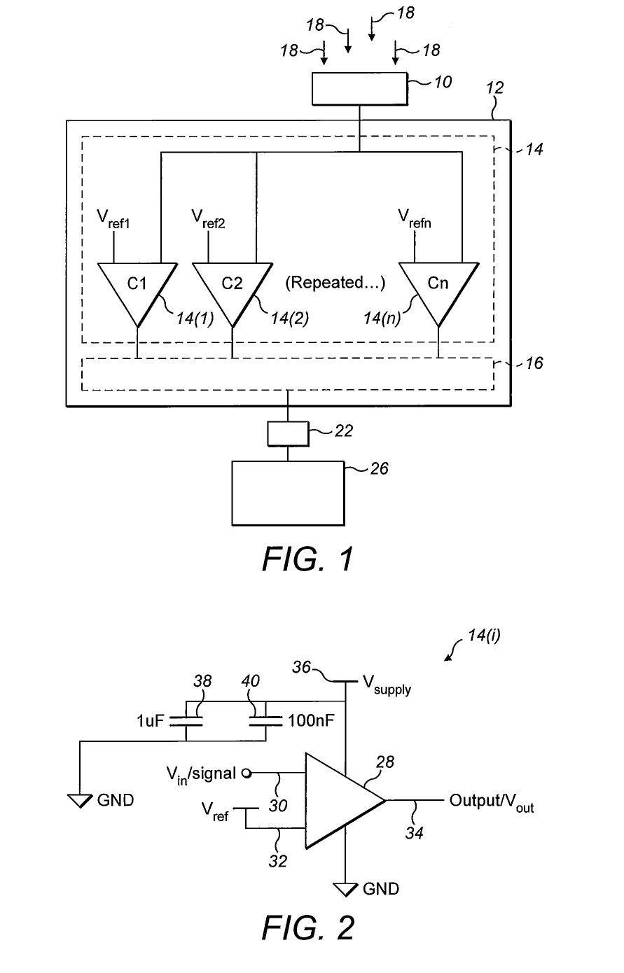

FIG. 1 illustrates a detector 10, an embodiment of a device 12 in accordance with the present disclosure, a digital acquisition card 22 and a computer 26. The device 12 comprises a plurality of comparator circuits 14 and a counter 16 for counting the number of outputs of a first type that have been output by the comparator circuits 14. The device 12 is arranged to output the count to computer 26 via digital acquisition card 22. Computer 26 is a computer comprising a processor and memory. In one implementation, the processor and memory are connected to a central bus structure and the computer also comprises a display connected to the central bus via a display adapter and one or more input devices (such as a mouse and/or keyboard), each being connected to the central bus structure via an input device adapter.

The detector 10 is arranged to detect a plurality of discrete events 18 which in the depicted embodiment are photon events 18. The detector 10 is arranged to produce an output electrical signal comprising a stream of pulses representing the detection of one or a stream of discrete events. Each pulse in the stream may correspond to either a single discrete photon event (a simple pulse) or to a plurality of discrete photon events occurring close together in time which will manifest as a complex pulse comprising an envelope of overlapping simple pulses. Suitably, each single pulse will have substantially the same amplitude, so that any complex pulse will have a combined or total amplitude which is in proportion to the number of simple pulses from which it is comprised. For example, a complex pulse will have substantially twice the amplitude of a single pulse when the complex pulse is formed from two simple pulses and will have substantially three times the amplitude of a single pulse when the complex pulse is formed from three simple pulses, and so on.

In FIG. 1 the plurality, n, of comparator circuits are illustrated. Each of these comparator circuits is labelled as Ci, with i ranging from i=1 to i=n. The figure shows a first comparator circuit C1 which is referenced as 14(1), a second comparator circuit C2 which is referenced as 14(2) and an nth comparator circuit Cn which is referenced as 14(n). As indicated in the figure the sequence of comparator circuits is continued from i=1 to i =n.

FIG. 2 shows in more detail the comparator circuit 14(i) that is used for each of comparators C1 to Cn of FIG. 1. The comparator circuit 14(i) comprises a comparator 28. The comparator 28 has two inputs: (i) Vin (30 in the figure) for receiving the input signal and (ii) Vref (32 in the figure) which sets a threshold value or reference voltage. The comparator also has an output, Vout (34 in the figure). The comparator is powered with a voltage supply 36 which is bypassed by two capacitors 38 and 40 to reduce the effects of voltage transients in the voltage supply on the operation of the comparator. The comparator circuit switches between an output of a first value when the signal is above the threshold value and an output of a second value when the signal is below the threshold value.

The first and second values are any of two binary states and for ease of reference the output of the comparator circuit will be described as being TRUE when the output is above the threshold value and FALSE when the output is below the threshold value. It will be appreciated that whether or not the output of the comparator circuit is TRUE or FALSE when the input signal equals the threshold is an implementation detail, and either setting could be used. In the comparator circuit shown in FIG. 2 the circuit will produce an output of TRUE when the signal (Vin) is greater or equal to the threshold value and will produce an output of FALSE when the signal (Vin) is less than the threshold value.

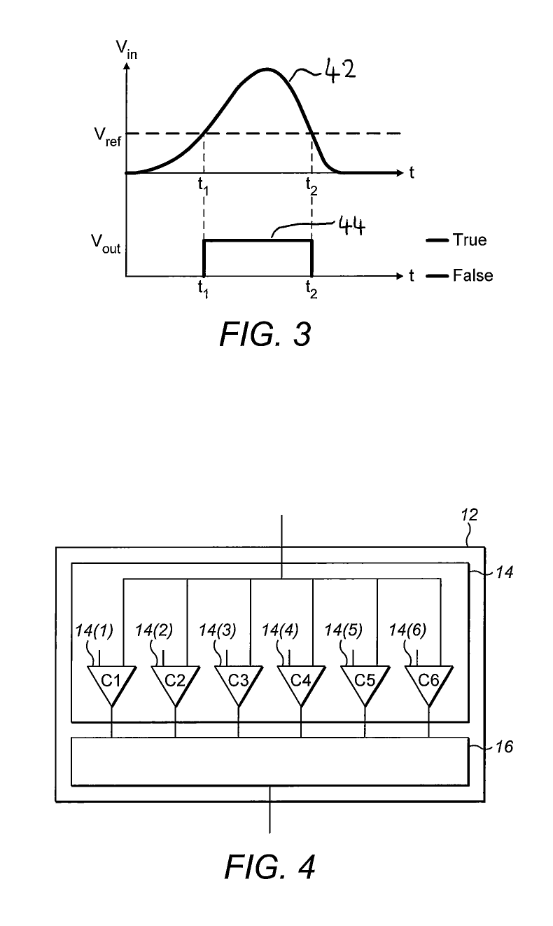

FIG. 3 illustrates how Vin for the comparator circuit 14(i) of FIG. 2 can vary over time for an electrical signal comprising a pulse 42. The output of the comparator is initially FALSE. When Vin exceeds Vref at time t1 the output 44 of the comparator circuit, Vout, causes the comparator circuit to switch its output from FALSE to TRUE. When Vin returns below the threshold at time t2 the comparator circuit produces an output of FALSE again.

FIG. 4 illustrates an embodiment of the device 12 in accordance with the present disclosure which comprises six comparator circuits 14 which are referenced as comparator circuits 14(1), 14(2), 14(3), 14(4), 14(5) and 14(6) in the figure. The structure used for each comparator circuit is as described above with reference to FIG. 2. A particular implementation of the device uses AD8611 single supply 4 ns comparator circuits from Analog Device Inc, Massachusetts, USA.

The device 12 of the embodiment of FIG. 4 reads or receives the signal that is output from the detector 10. The signal is read by each of the comparator circuits 14. Each comparator circuit has a threshold value set so that the output of the comparator circuit will be TRUE when a pulse of a certain amplitude is received. Suitably, the first comparator circuit has a threshold value which is set so that a pulse with an amplitude representing a single event will exceed the threshold value and give a TRUE output. Pulses having an amplitude representing two or more events will also exceed the threshold value for the first comparator circuit and give a TRUE output. The second comparator circuit has a threshold value which is set so that a pulse with an amplitude representing a single event will not exceed its threshold value but an amplitude of a pulse representing two or more events will exceed the threshold. Similarly, the third comparator circuit has a threshold value which is set so that an amplitude of a pulse representing a two events will not exceed its threshold value but an amplitude of a pulse representing three or more events will exceed the threshold. Similarly, corresponding thresholds will be set for the fourth, fifth and sixth comparator circuits. That is to say, the threshold voltage for each comparator circuit is set to be a level which is below the height of a pulse of level ‘i’ but above the level of a pulse of height ‘i-1’. In the described embodiment the threshold is set midway between the voltage levels of ‘i’ and ‘i-1’ height pulses (the 50% level). In other embodiments the threshold may be set at another suitable level, for example at a level between 50% and 80% of the relevant pulse height. Accordingly, it can be seen that in the described embodiment for each comparator circuit from i=1 to i=6, the i^{th} comparator circuit has a corresponding threshold value which the amplitude of a pulse representing i discrete events will exceed, but which the amplitude of a pulse representing i-1 discrete events will not exceed, and each comparator circuit outputs TRUE when the input signal equals or exceeds its threshold value and FALSE when the input signal is less than its threshold value.

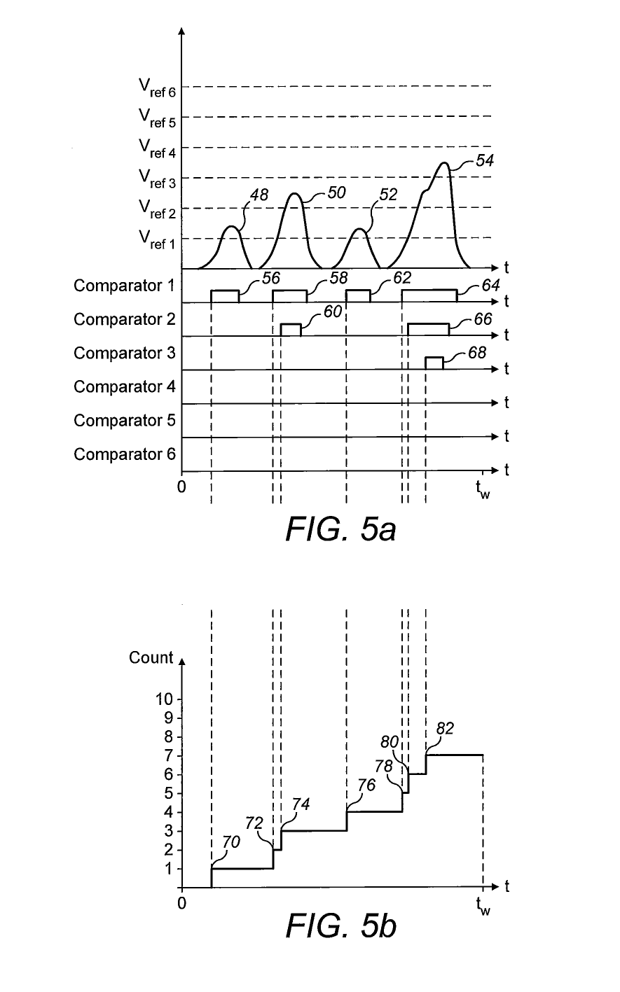

FIG. 5a illustrates how Vin can vary over time in a time window t=0 to t=tw for a signal comprising a stream or series of four pulses and how the signal is processed by the six comparator circuits of the device of FIG. 4. These pulses are simple pulse 48 (representing one event), complex pulse 50 (representing two events), simple pulse 52 (representing one event) and complex pulse 54 (representing three events). The comparator circuits 1 to 3 have outputs of TRUE 56, 58, 60, 62, 64, 66 and 68 when the respective threshold values are exceeded. Counting the number of TRUE outputs gives the number (seven) of discrete events represented by the signal. The count or number can be output to the digital acquisition card 22 at the end of the time window (i.e. when t=tw) and the count can be set to zero for a subsequent time window to be processed. In the embodiment of FIG. 4 tw=1 microsecond.

FIG. 5b illustrates how a counter can count the number of TRUE outputs produced by the six comparator circuits of the device of FIG. 4. As can be seen, each TRUE output contributes to the total count as the time progresses from t=0 to t=tw. The TRUE output 56 gives a count of 1 as represented by reference numeral 70, the TRUE output 58 increments the count to 2 as represented by reference numeral 72, the TRUE output 60 increments the count to 3 as represented by reference numeral 74, the TRUE output 62 increments the count to 4 as represented by reference numeral 74, the TRUE output 64 increments the count to 5 as represented by reference numeral 78, the TRUE output 66 increments the count to 6 as represented by reference numeral 80, and the TRUE output 68 increments the count to 7 as represented by reference numeral 72.

In the embodiment of FIG. 4 the counter 16 is implemented in a field programmable gate array (FPGA). The counter comprises binning circuitry implemented in the FPGA and a data bin is used for a time window having a predefined duration of t=tw.

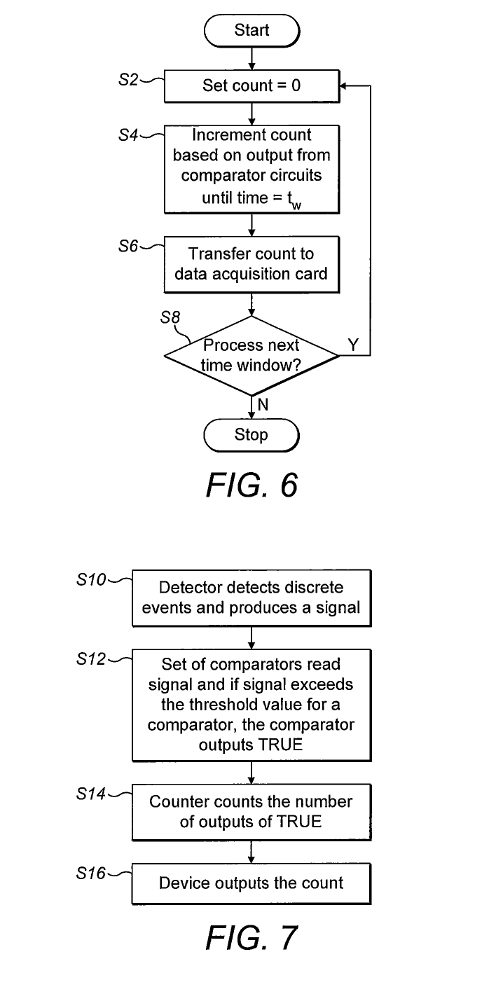

FIG. 6 is a flow diagram illustrating the steps performed by the counter 16 of FIG. 4 for the time window. Referring to the figure, at step S2 at the start of the time window (t=0) the count is set to zero for the data bin.

At step S4 the count is incremented based on the outputs from the comparator circuits 14 until t=tw. To do this, the binning circuitry of the FPGA monitors all of the comparator circuits continuously. When generating an output of TRUE a comparator circuit generates a logic level pulse which is fed in to the binning circuitry. When a full pulse profile has arrived (e.g. the first comparator circuit has gone through a full cycle of FALSE-TRUE-FALSE) the binning circuitry adds the number of TRUE outputs in that pulse to the data bin. For example, a pulse representing five events arrives, triggers five comparator circuits in the way described above, and five counts are added to the data bin. At the end of the time window, the count or number in the bin is transferred to the computer at step S6. If at step S8 if there is another time window to process the next time window is processed by returning to step S2, and the count for the bin is set to zero at the start of the time window (at t=0 for the time window). In the device of FIG. 4 the steps illustrated in FIG. 6 are performed as a continuous loop and whether or not data is processed is controlled by switching the digital acquisition card on and off One particular implementation of the device of FIG. 4 uses a Xilinx Spartan-3AN Non-volatile FPGA.

In the embodiment of FIG. 4 the count is transferred to the computer as a six bit binary code and the digital acquisition card 22 acts as an interface between the output of the counter 12 and the memory of the computer 26. The card 22 is connected to the counter via input lines through which the counter 12 outputs binary-encoded numbers and control signals. Upon receiving a control signal from the counter 22, the acquisition card 22 interrogates the input lines and reads a six-bit binary number corresponding to the current event count maintained in the counter. The six-bit binary number is then stored in temporary memory in the acquisition card 22. Instructions executed by the processor of computer 26 then control the transfer of the current event count from the acquisition card temporary memory into the memory of computer 26. One particular implementation of the device of FIG. 4 uses an Adlink PCI-7300 RevA high speed digital acquisition card.

The device of FIG. 4 can be reconfigured through activation or deactivation of any subset of the plurality of comparator circuits to change the response of the device to the pulsed input signal. A comparator circuit of the device of FIG. 4 is activated or deactivated by connecting or disconnecting its output. For example, all comparator circuits except comparator circuit C1 can be deactivated such that pulses output from a SPAD detector or a photomultiplier tube can be analysed and counted by the device despite the height of pulses from such a detector not being directly proportional to the number of photons incident on the detector during that pulse cycle. As another example, low-threshold comparator circuits can be deactivated such that any fluctuations and pulses below a certain height are ignored by the device, acting as a way of filtering noise signals that are not of significance to the system under investigation. It will be appreciated that the counter is able to operate irrespective of the number of comparator circuits that are activated.

FIG. 7 is a flow diagram illustrating the steps performed by the detector and an embodiment of a device 12 in accordance with the present disclosure such as the device illustrated in FIG. 4. At step S10, the detector detects discrete events and generates an electrical signal comprising a stream of electrical pulses. At step S12, the plurality of comparator circuits read the signal and if the signal exceeds the respective threshold value for a comparator circuit the comparator circuit outputs TRUE. At step S14, the counter counts the number of outputs of TRUE. At step S16, the device outputs the count. Optionally, as described above, the steps S12 to S16 can be performed in a defined time window and repeated to analyse the signal as it is read continuously, with the count being set to zero at the beginning of each iteration.

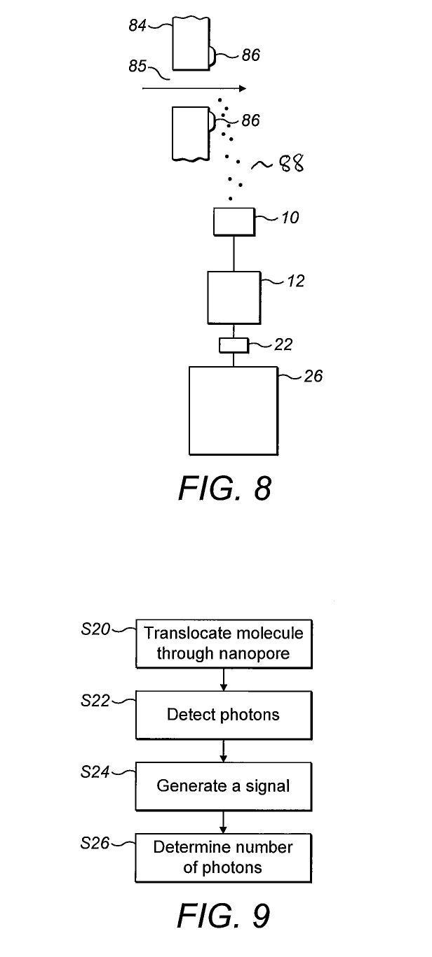

FIG. 8 illustrates a DNA sequencing apparatus comprising an analysing device 84, a detector 10, a device 12 in accordance with the present disclosure such as the device illustrated in FIG. 4, a digital acquisition card 22 and a computer 20. The analysing device 84 comprises a non-conducting membrane perforated with at least one nanopore 85 and an associated detection window comprised of a metallic plasmonic structure 86 (fabricated for example from gold or silver) juxtaposed around one of the openings of the nanopore. Typically, the nanopore is in the order of 1 nm to 100 nm in diameter, and optionally smaller (e.g. 1 nm to 30 nm, 1 nm to 10 nm, 1 nm to 5 nm or 2 nm to 4 nm) depending on the molecule being investigated. The analysing device can be configured to induce a target molecule (for example DNA) which has been suitably labelled with base-specific fluorescent markers to translocate though the nanopore from a suitable reservoir and into the detection window. In this embodiment, the plasmonic structures generate a localised electromagnetic field by plasmon reference which interacts with the fluorescent markers on the DNA causing them to fluoresce and emit photons which are captured by the detector. Such an analysing device is described in more detail in WO 2009/030953, the contents of which are incorporated herein in their entirety by reference.

As illustrated in FIG. 8 photons 88 produced by the fluorescing target molecule are detected by the detector 10 which comprises a single photon sensitive detector for detecting single photon events. In one implementation the detector comprises a silicon photomultiplier (SiPM). SiPMs include an array of cells, with each cell comprising a Geiger-mode avalanche photodiode (APD). When a photon hits an APD, the SiPM outputs an electrical pulse. For example, the amplitude of the electrical pulse output by the SiPM when two photons are detected simultaneously will be approximately double the amplitude of the electrical pulse output by the SiPM when a single photon is detected. The device 12 works in the way described above and can transfer the count of the number of photons to the computer 20.

FIG. 9 is a flow diagram illustrating the steps performed in a method of investigating a molecule in accordance with an embodiment of the present disclosure. At step S20 a molecule is translocated through a nanopore of an analysing device. The nanopore has a detection window and the analysing device is capable of plasmon resonance to produce a localised electromagnetic field which defines the detection window. At step S22, photons emitted during the interaction between the localised electromagnetic field and the molecule are detected as the molecule passes through the detection window. As step S24, a signal is generated containing one or more pulses representing a plurality of detected photons. At step S26, the number of detected photons represented by the signal is determined using an embodiment of a device in accordance with the present disclosure such as the device of FIG. 4.

Analysing the time-dependent photon count from the system after it has been captured to the computer memory allows the observation of dynamical behaviour of labelled biomolecules in the system, particularly the physical motion of molecules through the optical system. Such characterisation can elucidate internal structures of the molecules and give information as to their atomic and basic composition.

The above embodiments have been described by way of example only, and the described embodiments are to be considered in all respects only as illustrative and not restrictive. It will be appreciated that variations of the described embodiments may be made without departing from the scope of the invention which is indicated by the appended claims rather than by the foregoing description.

For example, in some embodiments the detection of pulsed electronic output signals can be made from other, non-optical detectors such as acoustic detectors, vibrational detectors, detectors of ionising nuclear radiation. Some embodiments may also be used for the analysis of pulsed signals from optical detectors which are not single-photon detectors but which exhibit pulsed behaviour with appropriate multi-level output in response to light signals.

Also, in some embodiments a digital acquisition card may not be used and the output of the device may be directly to the computer. Different comparator circuits, counters and computers may be used in some embodiments. For example, rather than using an FPGA the counter can be implemented using discrete logic integrated circuit (IC) elements.

Also, the TRUE output of the comparator circuits can have a value such as a binary 1 or other numerical value. Similarly, the FALSE output can have a value such as a binary 0 or other numerical value. In other embodiments the TRUE and FALSE outputs may be interchanged in other implementations so that the output is FALSE when the input signal exceeds the defined threshold and is TRUE when the input signal is less than the defined threshold. In such embodiments the counter would counting the number of outputs of FALSE that have been output by the plurality of comparator circuits.

Also, in some embodiments tw can be in the range from 100 nanoseconds to 1 millisecond, and can be in the range form 500 nanoseconds to 2 microseconds.

1. A device for determining the number of discrete events represented by an input signal, the input signal containing one or more pulses representing a plurality of discrete events, the device comprising:
a plurality, n, of comparator circuits for reading the signal, wherein for each comparator circuit from i=1 to i=n, the i^{th} comparator circuit has a corresponding threshold value which the amplitude of a pulse representing i discrete events will exceed, but which the amplitude of a pulse representing i-1 discrete events will not exceed, and wherein each comparator circuit is arranged to output a first value when the input signal exceeds its threshold value and a second value when the input signal is less than its threshold value; and
a counter for counting the number of outputs of the first value that have been output by the plurality of comparator circuits.

2. A device according to claim 1,
wherein the device is arranged to process the input signal as a series of time windows, wherein for each time window: the counter is set to zero at the beginning of the time window; the counter counts the number of outputs of the first value that have been output by the plurality of comparator circuits in the time window; and the device is arranged to output the count at the end of the time window.

3. A device according to claim 2, wherein the time window is in the range from 100 nanoseconds to 1 millisecond.

4. A device according to claim 3, wherein the time window is in the range from 500 nanoseconds to 2 microseconds.

5. A device according to claim 1, wherein the counter counts the number of outputs of the first value that have been output by the plurality of comparator circuits by monitoring the first comparator circuit for a period corresponding to a full pulse profile in which the first comparator circuit has gone through a complete cycle of outputs of the second value to the first value to the second value and counting once for the output of the first value of the first comparator circuit and once for each output of the first value of the other comparator circuits during the period.

6. A device according to claim 1, wherein the device is reconfigurable through activation or deactivation of any subset of the plurality of comparator circuits to change the response of the device to the pulsed input signal.

7. A device according to claim 1, wherein the counter is implemented in a field programmable gate array.

8. An apparatus comprising:
a device according to claim 1; and
a detector for detecting discrete events, wherein the detector is arranged to generate the signal containing one or more pulses representing a plurality of discrete events.

9. An apparatus according to claim 8, wherein the detector comprises a single photon sensitive detector and wherein the discrete events are single photon events.

10. An apparatus according to claim 9, wherein the detector comprises a silicon photomultiplier.

11. An apparatus according to claim 8, further comprising an analysing device for investigating a molecule wherein the analysing device is arranged to interact with the molecule to output photons.

12. An apparatus according to claim 11, wherein the analysing device comprises a nanopore having a detection window, and wherein the analysing device is capable of plasmon resonance to produce a localised electromagnetic field which defines the detection window.

13. A method of investigating a molecule comprising:
translocating a molecule through an analysing device, comprising a nanopore and a detection window and wherein the analysing device is capable of plasmon resonance to produce a localised electromagnetic field which defines the detection window;
detecting photons emitted during the interaction between the localised electromagnetic field and the molecule as the molecule passes through the detection window;
generating a signal containing one or more pulses representing a plurality of detected photons; and
determining the number of detected photons represented by the signal using a device according to claim 1.

14. The method of claim 13, wherein the molecule is a biological molecule.

15. The method of claim 14, wherein the molecule is a nucleic acid.
